(19) United States
(12) Patent Application Publication
(10) Pub. No.: US 2022/0294030 A1
(43) Pub. Date: Sep. 15, 2022

(54) BATTERY MODULE ELEMENT, METHOD FOR PRODUCING SUCH A BATTERY MODULE ELEMENT AND A BATTERY MODULE

(71) Applicant: Robert Bosch GmbH, Stuttgart (DE)

(72) Inventors: Benjamin Kopp, Remseck Am Neckar (DE); Markus Schmitt, Tamm (DE); Robert Kohler, Stuttgart (DE); Roman Marx, Moensheim (DE)

(21) Appl. No.: 17/689,180

(22) Filed: Mar. 8, 2022

(30) Foreign Application Priority Data
Mar. 9, 2021 (DE) 102021202286.3

(51) Int. Cl. H01M 10/42; H01M 10/6568; H01M 10/6556

(52) U.S. Cl. CPC H01M 10/425; H01M 10/6568; H01M 10/6556

(57) ABSTRACT

A battery module element with a housing element (2) of a battery module on which an electrical circuit board (3) is arranged on a first side (21) of the housing element (2), wherein an inductor (6) is arranged on the electrical circuit board (3) in such a mechanical manner that at least one end (71) of a coil winding (7) of the inductor (6) is arranged running through the electrical circuit board (3) and is connected to the housing element (2) in a thermally conductive manner, and wherein the housing element (2) comprises a temperature control structure (5), around which temperature control fluid can flow, on a second side (22) opposite the first side (21), so that heat can be transferred from the coil winding (7) to the temperature control fluid.

### BACKGROUND OF THE INVENTION

The invention is based on a battery module element. Furthermore, the invention also relates to the production of such a battery module element and to a battery module.

It is known from the prior art that a battery module has a plurality of individual battery cells which each have a positive voltage tap and a negative voltage tap, wherein the respective voltage taps are connected to one another in an electrically conductive manner to form an electrically conductive serial and/or parallel connection of the plurality of battery cells with one another and they can thus be interconnected to form the battery module. Battery modules for their part are interconnected to form batteries or to form entire battery systems.

Owing to a multiplicity of possible different vehicle installation spaces, variable module sizes should be the aim in order to make optimum use of the available installation space.

Furthermore, the battery cells of a battery module, such as lithium-ion battery cells or lithium-polymer battery cells, for example, heat up during operation caused by chemical transformation processes based on their electrical resistance in the case of power output or power consumption. In particular, these processes are comparably pronounced in the case of comparably fast energy output or energy consumption.

The more powerful a battery or a battery module is, the more pronounced is the resulting heating and consequently the requirements for an efficient temperature control system. In order to increase the safety of a battery module and also to ensure the efficiency of the battery cells, the battery cells of a battery module are to be both heated and cooled, in order to be able to operate them in a specific temperature range as far as possible, so that increased ageing behavior or decomposition of the cell chemistry can be prevented, for example.

However, the battery cells are predominantly to be cooled

Temperature control, i.e. heating or heat dissipation, of the battery can be formed by fluid temperature control with a water/glycol mixture, for example. In this case, this mixture can be directed by cooling plates arranged below the battery module. The cooling plate can in this case be connected to a corresponding component of a cooling circuit.

In addition, the further electronic components of a battery module or a battery, for example, are also to be temperature controlled.

Examples of prior art are EP 2023473 and US 2019/0335608.

### SUMMARY OF THE INVENTION

A battery module element offers the advantage that reliable temperature control, in particular of an inductor, can be formed.

A battery module element is provided according to the invention for this purpose. In this case, the battery module element comprises a housing element of the battery module on which an electrical circuit board is arranged on a first side. In this case, an inductor is arranged on the electrical circuit board in such a mechanical manner that at least one end of a coil winding of the inductor is arranged running through the electrical circuit board and furthermore is connected to the housing element in a thermally conductive manner. In this case, the housing element comprises a temperature control structure, around which temperature control fluid can flow, on a second side opposite the first side. Heat can thus be transferred from the coil winding to the temperature control fluid.

An inductor is in this context understood to mean a passive electrical and/or electronic component with a fixed or adjustable inductance value.

The housing element is in particular formed from a metallic material. Furthermore, the housing element can be formed from a material with a comparably high thermal conductivity.

A mechanical arrangement should in this context be understood to mean that the at least one end of the coil winding of the inductor is arranged running through the electrical circuit board and can, for example, additionally be pressed into it.

It is particularly advantageous if the at least one end of the coil winding of the inductor is arranged directly adjacent to the temperature control structure, in particular the at least one end is arranged above the temperature control structure. This should be understood to mean that the shortest possible distance is formed between the at least one end of the coil winding of the inductor and the temperature control structure. In particular, the temperature control structure which is arranged directly adjacent to the inductor can be optimized to dissipate heat.

Two ends of the coil winding of the inductor are particularly preferably arranged on the circuit board. In particular, the two ends of the coil winding are arranged on the circuit board in a mechanical and electrical manner. An electrical arrangement should in this context be understood to mean that the end of the coil winding of the inductor is connected to the electrical circuit board in an electrically conductive manner.

It is particularly advantageous if the at least one end of the coil winding of the inductor is received in a recess of the housing element. This receptacle is particularly preferably designed to be thermally conductive. As a result, a particularly reliable heat transfer from the at least one end of the coil winding of the inductor to the housing element is possible. In particular, this can increase the heat-transferring surface and also form a reliable attachment.

It is also advantageous if the electrical circuit board has at least one opening which in particular is designed to run through the electrical circuit board. In this case, a protrusion of the housing element is received in the at least one opening. This receptacle is particularly preferably designed to be thermally conductive. As a result, it is possible to link the electrical circuit board to the housing element in a thermally conductive manner. Furthermore, in the case of an opening running through the electrical circuit board, the coil winding, for example a central region of the coil winding, can also be linked to the housing element in a thermally conductive manner. For this purpose, the at least one opening can be arranged below the inductor, for example.

According to one preferred aspect of the invention, a thermal compensation material is arranged between the at least one end of the coil winding of the inductor and the housing element, in particular the recess. According to one further preferred aspect of the invention, a thermal compensation material is arranged between the electrical circuit board and/or the coil winding and the housing element, in particular the protrusion.

For this purpose, the thermal compensation material can be arranged in the recess of the housing element and/or the opening of the electrical circuit board, for example during production. In particular, a gap filler can be dispensed for this purpose, for example. During production, when arranging the electrical circuit board on the housing element, the at least one end of the coil element dives into the recess and thereby forms a reliable mechanical and thermal contact. In particular, a part of the thermal compensation material can also be displaced in this case, which can escape through a gap between the electrical circuit board and the recess. In addition, the protrusion of the housing element dives into the opening of the electrical circuit board during production and thereby forms a reliable mechanical and thermal contact. In particular, a part of the thermal compensation material can also be displaced in this case, which can escape through a gap between the electrical circuit board and the protrusion.

As a result, the at least one end of the coil winding of the inductor, on the one hand, and also the electrical circuit board, on the other hand, can be arranged on the housing element in a thermally conductive manner.

A thermal compensation material is used to compensate for irregularities or undesired spacing between individual elements and consequently to form reliable thermal conduction.

It is particularly advantageous if the temperature control structure comprises at least one flow directing element and/or at least one flow disruptor element. Flow directing elements are used here in particular to guide and redirect a temperature control fluid flow. Flow disruptor elements are used here in particular to increase a turbulence of a temperature control fluid flow and in particular to form a transition from a laminar to a turbulent flow. Flow directing elements and/or flow disruptor elements can be arranged here corresponding to the thermal requirements of a cooling system, such as the inductor, the electrical circuit board or even further electrical or electronic components, for example. In particular, flow disruptor elements can be arranged at points or regions of the housing element which require comparably intensive cooling. The remaining regions can be designed to optimize flow and pressure loss.

It is particularly advantageous if a cover element is arranged on the housing element in such a way that a temperature control channel through which the temperature control fluid can flow is formed. It should be noted at this point that temperature control fluid flowing in the temperature control channel in particular flows around or along the temperature control structure.

The housing element can further have an inlet, which is designed for the temperature control fluid to flow into the temperature control channel, and an outlet, which is designed for the temperature control fluid to flow out of the temperature control channel. The housing element can particularly preferably be designed in such a way that a u-shaped flow guide is formed.

The housing element is advantageously formed as a die casting. In particular, the recess and/or the protrusion are also formed in the die casting in this case. In addition, the temperature control structure, such as the at least one flow directing element and the at least one flow disruptor element, for example, are in particular also formed in the die casting in this case.

One particular advantage of the invention is that the inductor can be linked to the temperature control structure of the housing element in a thermally conductive manner.

Furthermore, the invention also relates to a battery module with a battery module element according to the invention.

The invention further also relates to a method for producing a battery module element according to the invention. In this case, on a housing element of a battery module, an electrical circuit board is arranged on a first side, wherein an inductor is arranged on the electrical circuit board in such a mechanical manner that at least one end of a coil winding of the inductor is arranged running through the electrical circuit board and is connected to the housing element in a thermally conductive manner. In this case, the housing element comprises a temperature control structure, around which temperature control fluid can flow, on a second side opposite the first side, so that heat can be transferred from the coil winding to the temperature control fluid.

The method according to the invention can of course be further developed in terms of the battery module element according to the invention.

### BRIEF DESCRIPTION OF THE DRAWINGS

Exemplary embodiments of the invention are represented in the drawings and are explained in greater detail in the subsequent description.

In the drawings:

FIG. 1 shows a cut-out of a perspective view on a first side of the housing element,

FIG. 2 shows a second side of the housing element,

FIG. 3 shows an inductor arranged on a circuit board and

FIG. 4 shows a sectional view of a battery module element according to the invention.

### DETAILED DESCRIPTION

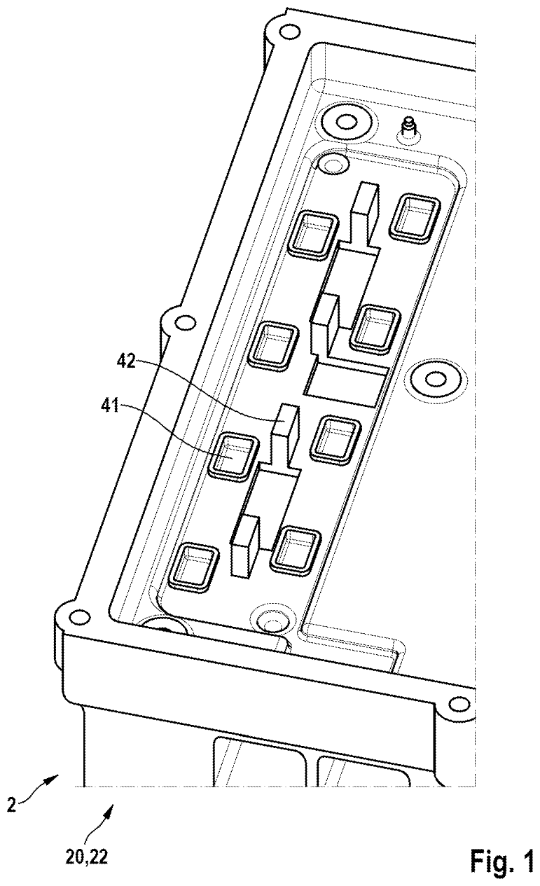

FIG. 1 shows a cut-out of a perspective view on a first side 21 of a housing element 2 of a battery module. In this case, the housing element 2 of the battery module is formed as a die casting 20.

An electrical circuit board 3 which is not shown in FIG. 1 can be arranged on the first side 21.

It can be recognized from FIG. 1 that a recess 41 of the housing element 2 can be formed on the first side 21 of the housing element 2, for example.

In addition, it can also be recognized from FIG. 1 that a protrusion 42 of the housing element 2 can be formed on the first side 21 of the housing element 2, for example.

In particular, the recess 41 and the protrusion 42 are formed by the die casting 20.

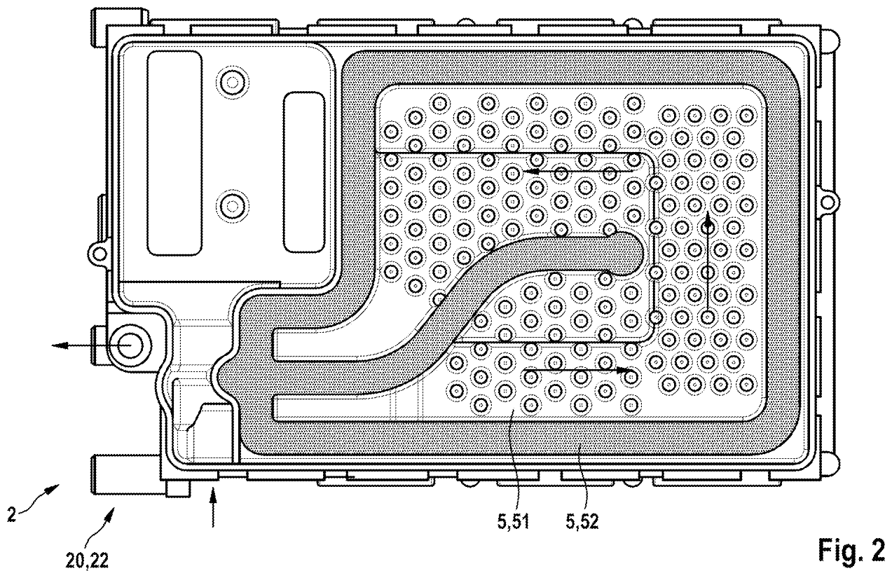

FIG. 2 shows a second side 22 of the housing element 2. In this case, the second side 22 of the housing element 2 is arranged opposite the first side 21 of the housing element 2.

In this case, the housing element 2 comprises a temperature control structure 5, around which temperature control fluid can flow, on the second side 22. In this case, the temperature control structure 5 comprises a flow directing element 52 and a plurality of flow disruptor elements 51.

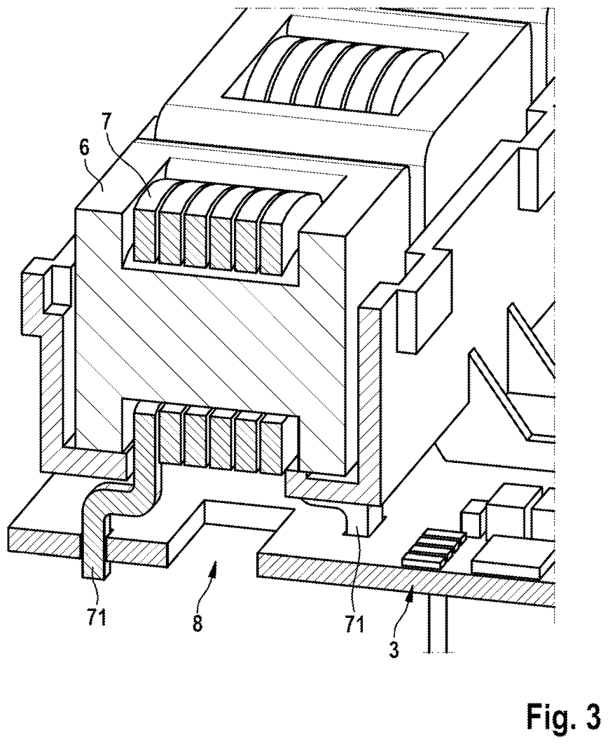

FIG. 3 shows an inductor 6 arranged on a circuit board 3. It should also be noted at this point that FIG. 3 represents a sectional view.

In this case, the inductor 6 is arranged on the electrical circuit board 3 in a mechanical manner. In this case, the inductor 6 comprises a coil winding 7. The ends 71 of the coil winding 7 of the inductor 6 are arranged running through the electrical circuit board 3 in this case. In particular, two ends 71 of the coil winding 7 of the inductor 6 are arranged on the circuit board 3 in a mechanical and electrical manner.

In this case, the ends 71 of the coil winding 7 of the inductor 6 can be received in the recess 41 shown in FIG. 1 of the housing element 2.

Furthermore, it can also be recognized in FIG. 3 that the electrical circuit board 3 has an opening 8. In this case, the opening 8 is designed to run through the electrical circuit board 3.

In this case, a protrusion 42 shown in FIG. 1 of the housing element 2 can be received in the opening 8 of the housing element 2.

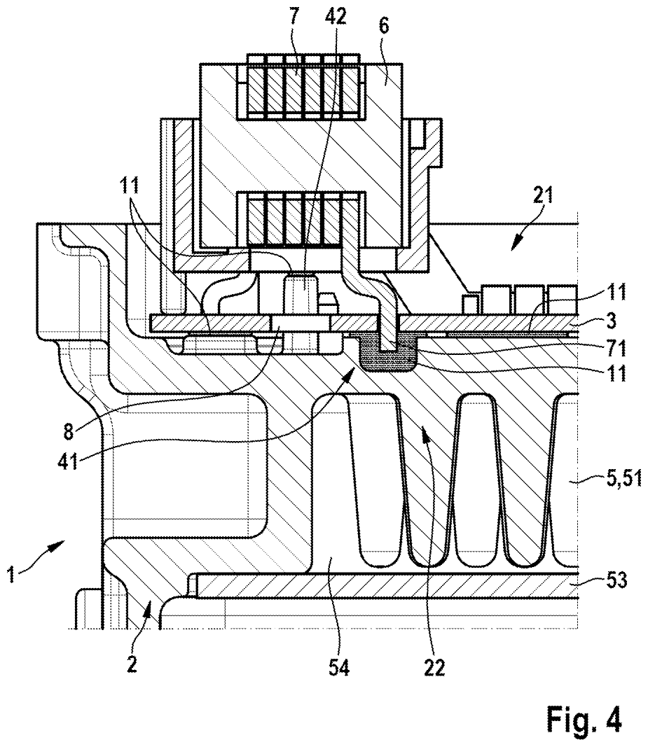

FIG. 4 shows a sectional view of a battery module element 1 according to the invention.

In this case, the housing element 2 of the battery module can be recognized, on which the electrical circuit board 3 is arranged on the first side 21. In this case, the inductor 6 is arranged on the electrical circuit board 3 in such a mechanical manner that the ends 71 of the coil winding 7 of the inductor 6 are arranged running through the electrical circuit board 3 and are connected to the housing element 2 in a thermally conductive manner.

Furthermore, it can be recognized that the temperature control structure 5, around which temperature control fluid can flow, is formed on the second side 22 opposite the first side 21. Heat can thus be transferred from the coil winding 7 to the temperature control fluid.

In this case, a cover element 53 is arranged on the housing element 2 in such a way that a temperature control channel 54 through which the temperature control fluid can flow is formed.

In this case, the end 71 of the coil winding 7 is arranged directly adjacent to the temperature control structure 5 and in particular also to the temperature control channel 54.

Furthermore, it can be recognized in FIG. 4 that the end 71 of the coil winding 7 of the inductor 6 is received in the recess 41 of the housing element 2.

It can further be recognized in FIG. 4 that the protrusion 42 of the housing element 2 is received in the opening 8 of the electrical circuit board 3.

In this case, a thermal compensation material 11 is arranged between the ends 71 of the coil winding 7 of the inductor 6 and the housing element 2 or in particular the recess 41. Furthermore, a thermal compensation material 11 is also arranged between the coil winding 7 and the housing element 2 or in particular the protrusion 42. Furthermore, a thermal compensation material 11 can also be arranged between the electrical circuit board 3 and the housing element 2.

In addition, flow disruptor elements 51 of the temperature control structure 5 can be recognized in FIG. 4.

In this case, heat can, for example, be transferred from the coil winding 7 to the protrusion 42, from the end 71 of the coil winding 7 to the recess 41 and from the electrical circuit board 3 to the housing element 2. In summary, heat can therefore be transferred in a reliable manner from the inductor 6 and the electrical circuit board 3 to the housing element 2. This heat can then be directed from the housing element 2 in the direction of the temperature control structure 5. Furthermore, the temperature control structure 5 transfers the heat to the temperature control fluid. The inductor 6 and the electrical circuit board 3 can thus transfer heat in a reliable manner to the temperature control fluid, which enables heat dissipation from the inductor 6 and the electrical circuit board 3.

1. A battery module element comprising:
a housing element (2) of a battery module on which an electrical circuit board (3) is arranged on a first side (21) of the housing element (2), wherein an inductor (6) is arranged on the electrical circuit board (3) in such a mechanical manner that at least one end (71) of a coil winding (7) of the inductor (6) is arranged running through the electrical circuit board (3) and is connected to the housing element (2) in a thermally conductive manner, and wherein the housing element (2) includes a temperature control structure (5), around which temperature control fluid can flow, on a second side (22) opposite the first side (21), so that heat can be transferred from the coil winding (7) to the temperature control fluid.

2. The battery module element according to claim 1, wherein two ends (71) of the coil winding (7) of the inductor (6) are arranged on the circuit board (3).

3. The battery module element according to claim 2, wherein the two ends (71) of the coil winding (7) of the inductor (6) are arranged on the circuit board (3) in a mechanical and electrical manner.

4. The battery module element according to claim 1, wherein the at least one end (71) of the coil winding (7) of the inductor (6) is received in a recess (41) of the housing element (2).

5. The battery module element according to claim 1, wherein the electrical circuit board (3) has at least one opening (8), and a protrusion (42) of the housing element (2) is received in the at least one opening (8).

6. The battery module element according to claim 5, wherein the opening (8) is extends through the electrical circuit board (3).

7. The battery module element according to claim 1, wherein a thermal compensation material (11) is arranged between the at least one end (71) of the coil winding (7) of the inductor (6) and the housing element (2),

8. The battery module element according to claim 7, wherein the thermal compensation material (11) is arranged in the recess (41).

9. The battery module element according to claim 7, wherein the thermal compensation material (11) is arranged between the electrical circuit board (3) and the housing element (2).

10. The battery module element according to claim 1, wherein the temperature control structure (5) includes at least one flow directing element (52) and/or at least one flow disruptor element (51).

11. The battery module element according to claim 1, wherein a cover element (53) is arranged on the housing element (2) in such a way that a temperature control channel (54) through which the temperature control fluid can flow is formed.

12. The battery module element according to claim 1, wherein the housing element (2) is formed as a die casting (20).

13. The battery module with a battery module element (1) according to claim 1.

14. A method for producing a battery module element (1) according to claim 1, wherein on a housing element (2) of a battery module, the method comprises arranging an electrical circuit board (3) on a first side (21) of the housing element (2), and arranging an inductor (6) on the electrical circuit board (3) in such a mechanical manner that at least one end (71) of a coil winding (7) of the inductor (6) is arranged running through the electrical circuit board (3) and is connected to the housing element (2) in a thermally conductive manner, and wherein the housing element (2) comprises a temperature control structure (5), around which temperature control fluid can flow, on a second side (22) opposite the first side (21), so that heat can be transferred from the coil winding (7) to the temperature control fluid.
